(19) United States
(12) Patent Application Publication
(10) Pub. No.: US 2026/0271220 A1
(43) Pub. Date: Sep. 10, 2026

(54) COOLING ACCESSORY

(71) Applicant: CANON KABUSHIKI KAISHA, Tokyo (JP)

(72) Inventor: HARUHISA UEDA, Kanagawa (JP)

(21) Appl. No.: 19/550,800

(22) Filed: Feb. 26, 2026

(30) Foreign Application Priority Data
Mar. 10, 2025 (JP) 2025-037102

(51) Int. Cl. H05K 7/20; G03B 17/55

(52) U.S. Cl. CPC H05K 7/20145; G03B 17/55; H05K 7/20154

(57) ABSTRACT

A cooling accessory is attachable to an electronic apparatus and includes an exterior surface having a first intake and exhaust port configured to intake and exhaust a fluid inside the electronic apparatus, a cooling duct through which the fluid flows, and a cooling unit provided inside the cooling duct. The cooling unit is configured to move the fluid between an inside of the electronic apparatus and an inside of the cooling duct through the first intake and exhaust port. The first intake and exhaust port has a shape that is longer in a second direction than in a first direction in an in-plane direction of the exterior surface. The cooling duct includes a first region and a second region disposed closer to the cooling unit than the first region. The first region in the first direction is narrower than the second region in the first direction.

### BACKGROUND

### Field of the Technology

The present disclosure relates to a cooling accessory.

### Description of the Related Art

Japanese Patent Application Laid-Open No. 2019-219458 discloses an image pickup apparatus that has an intake port (air inlet) and an exhaust port formed in a rear cover of the image pickup apparatus, and a duct formed by the rear cover and a display unit. Japanese Patent Application Laid-Open No. 2012-198447 discloses a camera cooling system having a blower that sends air into the internal space of the image pickup apparatus when the image pickup apparatus is attached.

However, the image pickup apparatus disclosed in Japanese Patent Application Laid-Open No. 2019-219458 has no blower that passes air through the duct, and thus has lower cooling capacity than that of an apparatus with a blower. Furthermore, the degree of freedom in the arrangement of the intake and exhaust ports is limited.

In the camera cooling system disclosed in Japanese Patent Application Laid-Open No. 2012-198447, the intake port of the image pickup apparatus is located in a tripod attachment unit, and thus the placement of the intake port is limited. Furthermore, since the blower is attached to the bottom surface of the image pickup apparatus, the size of the image pickup apparatus increases in a height direction, and portability lowers. In a case where the image pickup apparatus is fixed to the tripod or image stabilizing gimbal while the blower is attached to the bottom surface, the position of the imaging optical axis becomes higher from the bottom fixing unit, and thus image blur due to vibration, etc. increases. On the other hand, a flow path for air blowing cannot be secured on the side surfaces other than the bottom surface of the image pickup apparatus because it interferes with the grip portion, cable connection terminals, movable display unit, and the like, so cooling performance lowers.

### SUMMARY

A cooling accessory according to one aspect of the present disclosure may be attachable to an electronic apparatus. The cooling accessory may include an exterior surface having a first intake and exhaust port configured to intake and exhaust a fluid inside the electronic apparatus, a cooling duct through which the fluid flows, and a cooling unit provided inside the cooling duct. The cooling unit may be configured to move the fluid between an inside of the electronic apparatus and an inside of the cooling duct through the first intake and exhaust port. The first intake and exhaust port may have a shape that is longer in a second direction than in a first direction in an in-plane direction of the exterior surface. The cooling duct may include a first region and a second region disposed closer to the cooling unit than the first region. The first region in the first direction may be narrower than the second region in the first direction.

Features of the present disclosure will become apparent from the following description of embodiments with reference to the attached drawings. The following description of embodiments is described by way of example.

### BRIEF DESCRIPTION OF THE DRAWINGS

FIGS. 1A and 1B are perspective views of an image pickup apparatus according to this embodiment.

FIGS. 2A and 2B are external views of a cooling accessory according to this embodiment.

FIG. 3 is an exploded perspective view of the cooling accessory according to this embodiment.

FIGS. 4A and 4B are external views of an imaging system according to this embodiment.

FIGS. 5A and 5B are external views of the imaging system according to this embodiment.

FIGS. 6A and 6B are block diagrams of the imaging system according to this embodiment.

FIGS. 7A and 7B are sectional views of the imaging system according to this embodiment.

FIGS. 8A and 8B are schematic diagrams of the imaging system according to this embodiment.

FIG. 9 is a sectional view of the imaging system according to this embodiment.

FIG. 10 is a sectional view of the imaging system according to this embodiment.

### DESCRIPTION OF THE EMBODIMENTS

Hereinafter, embodiments of the present disclosure will be described in detail with reference to the drawings. The present embodiments are merely examples as means for achieving the present disclosure, and may be properly modified or changed according to the structure of an apparatus to which the present disclosure is applied or a variety of conditions. In addition, the embodiments may be combined with each other as appropriate.

### STRUCTURE OF CAMERA BODY 100

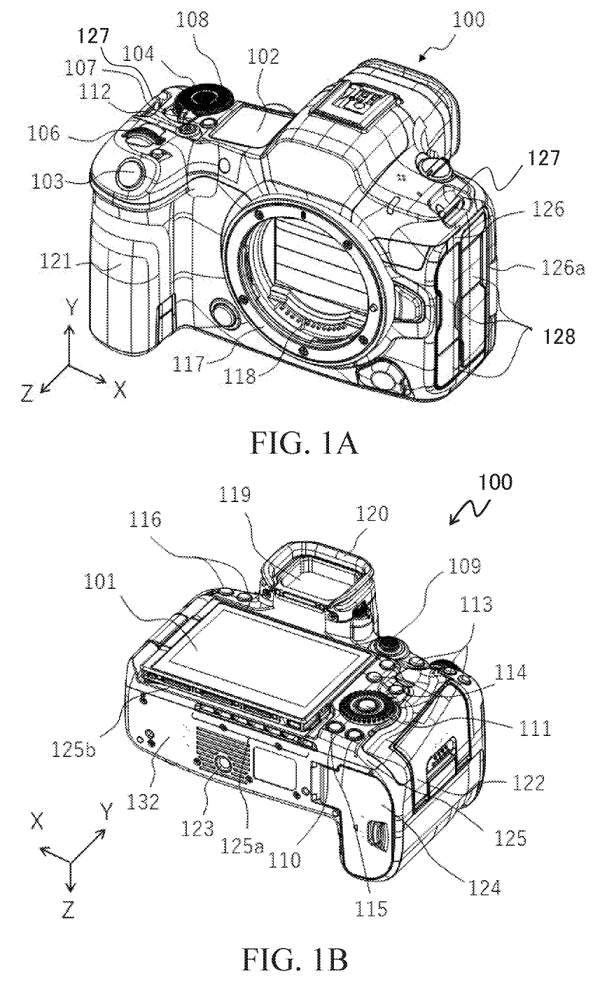

First, with reference to FIGS. 1A and 1B, a camera body (image pickup apparatus, electronic apparatus) 100 according to the present embodiment will be described. FIGS. 1A and 1B are external views of the camera body 100. FIG. 1A illustrates the camera body 100 viewed from the front, and FIG. 1B illustrates the camera body 100 viewed from the rear. In the present embodiment, the width direction (lateral direction, horizontal direction) of the camera body 100 is defined as an X direction (third direction), the height direction (vertical direction) of the camera body 100 is defined as a Y direction (second direction), and a direction perpendicular to the imaging surface of an image sensor (optical-axis direction) is defined as a Z direction (first direction).

A rear display unit (movable display unit) 101 provided on the rear side of the camera body 100 is attached to the camera body 100 so as to be openable, closable, and rotatable, and displays images generated by imaging (image capturing) and various types of information on imaging. The rear display unit 101 includes a touch panel and can detect a touch operation performed by the user on its display surface (operation surface). A top display unit 102 provided on the top surface of the camera body 100 can display setting values of a variety of imaging parameters such as shutter speed and aperture value (F-number).

A shutter button 103 is an operation member operable by the user to instruct imaging by the camera body 100. A mode switch 104 is an operation member operable by the user to switch among a variety of modes. A main electronic dial 106 is an operation member rotatable by the user to change setting values of imaging parameters. A power switch 107 is an operation member operable by the user to switch between the power-on and power-off of the camera body 100. A sub electronic dial 108 is an operation member operable by the user to move a selection frame such as a focus detecting (autofocus (AF)) frame or to perform image feeding.

A terminal cover 128 is a cover that protects a connector (terminal portion) to which a connection cable extending from the external apparatus can be connected.

A multi-controller 109 is provided on the rear surface of the camera body 100. The multi-controller 109 is configured to accept input by a pressing operation of a key top and tilting operations in upward, downward, leftward, rightward, and diagonal directions. By operating the multi-controller 109, the user can move a selection frame or select items in a variety of menus.

A rear electronic dial 110 is an operation member operable by the user to move a selection frame or to perform image feeding. The rear electronic dial 110 is disposed at a position that allows intuitive operation by the user while captured images are displayed on the rear display unit 101, and also allows easy operation even when the user holds the camera body 100 in a vertical orientation. A setting button 111 is provided at a central portion of the rear electronic dial 110. The setting button 111 is an operation member in the form of a push button operable by the user to confirm a selected item or the like.

A moving image capturing button 112 is an operation member operable by a user to instruct the start and stop of moving image recording. A button group A 113 includes operation members regarding focus and exposure, and includes an AF start button, an auto-exposure (AE) lock button, and an AF frame selecting button arranged side by side. By pressing the button group A 113 in an imaging standby state, the user can start AF, change an AF frame, or lock exposure.

A button group B 114 includes a magnification/reduction button, an information display button, and a quick setting button arranged in an L shape. By operating the magnification/reduction button in a live-view display state in an imaging mode, the user can switch between turning on and turning off of the magnification for a live-view display image. By operating the magnification/reduction button in a playback mode, the user can switch between turning on and turning off of the magnification of a captured image that is being displayed.

By operating the information display button, the user can switch display methods of information displayed on the rear display unit 101. By operating the quick setting button, the user can immediately transition the display of the rear display unit 101 to a screen for changing setting values of imaging parameters.

A button group C 115 includes a playback button and a delete button. By operating the playback button, the user can switch between an imaging mode and a playback mode. When the playback button is operated in the imaging mode, the camera transitions to the playback mode, and the latest captured image among captured images recorded on an unillustrated medium can be displayed on the rear display unit 101. In the playback mode, by operating the delete button, the user can delete a selected captured image.

A button group D 116 includes a menu button and a rating button. When the user operates the menu button, a menu screen that displays configurable items is displayed on the rear display unit 101. The user can intuitively select items and perform settings by performing touch operations on the menu screen displayed on the rear display unit 101, or by operating the multi-controller 109, the rear electronic dial 110, and the setting button 111. In the playback mode, by operating the rating button, the user can assign a rating to a playback image.

An unillustrated interchangeable lens is detachably attached to a mount unit 117. A communication terminal 118 provided inside the mount unit 117 is used for communication between the camera body 100 and the interchangeable lens.

A finder (viewfinder) 119 provided on an upper rear portion of the camera body 100 is an electronic viewfinder that allows a user looking into it to visually recognize a live-view display image or the like. An eyepiece cover 120 is a rubber member that comes into contact with a facial area around the eye of a user looking into the finder 119.

A grip portion 121 is a grip unit having a shape that allows the user holding the camera body 100 to easily grip it with the right hand. A card cover (card lid) 122 is a cover that covers a media slot 153 (not illustrated) for storing a medium (not illustrated). The card cover 122 is provided at a portion of the grip portion 121 that comes into contact with the user’s palm.

A tripod seat (tripod socket) 123 is an attachment member used when an external accessory is attached to a bottom surface of the camera body 100. A battery cover (battery lid) 124 is a cover for storing a battery (not illustrated). The card cover 122 is detachably attached to a bottom exterior member 132.

A rear exterior member 125 is an exterior member forming a rear surface of the camera body 100 among exterior members constituting the camera body 100, and is formed of metal, polycarbonate, or the like. The rear exterior member 125 includes a body intake and exhaust port 125a on a bottom surface side of the camera body 100, and a housing-portion exterior surface 125b for housing the rear display unit 101.

A side exterior member 126 is an exterior member that forms a left side surface of the camera body 100 when viewed from the rear among exterior members constituting the camera body 100, and is made of metal, polycarbonate, or the like. The side exterior member 126 includes a body intake and exhaust port 126a provided in the camera body 100. A bottom exterior member 132 is an exterior member that forms a bottom surface of the camera body 100 among exterior members constituting the camera body 100, and is made of metal, polycarbonate, or the like.

Eyelets 127 for hooking a strap are metal members provided on left and right sides of a top surface of the camera body 100, and are connected to a metal housing or exterior members of the camera body 100.

### STRUCTURE OF COOLING ACCESSORY 200

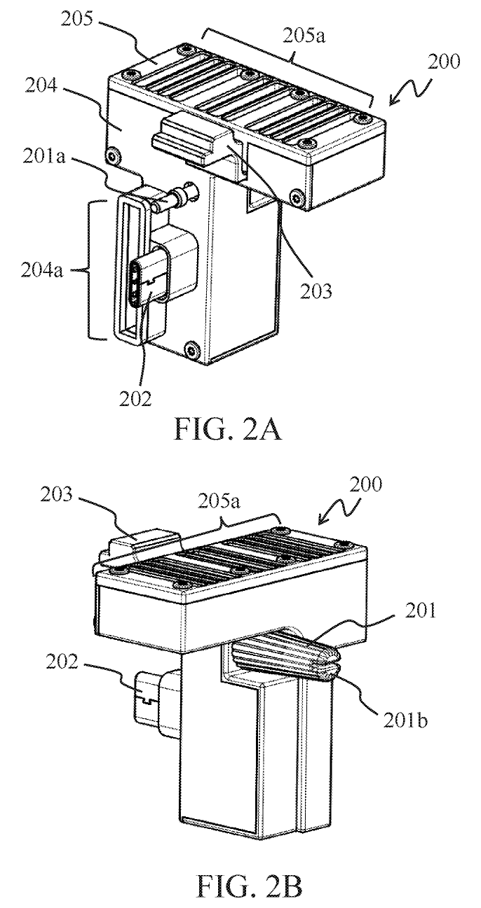

Next, with reference to FIGS. 2A and 2B, an external structure of a cooling accessory (accessory apparatus, cooling apparatus) 200 according to the present embodiment will be described. FIGS. 2A and 2B are external views of the cooling accessory 200. FIG. 2A is a view from an attachment surface to the camera body 100, and FIG. 2B is a view from a side opposite to the attachment surface to the camera body 100. The cooling accessory 200 is attachable to the camera body 100.

The cooling accessory 200 includes an attachment screw (fixing member) 201 for attaching (fixing) the cooling accessory 200 to the camera body 100. The attachment screw 201 includes a screw portion 201a protruding toward the attachment surface to the camera body 100. The attachment screw 201 further includes, on a side opposite to the attachment surface to the camera body 100, a screw tightening portion 201b to be fastened by a user.

The cooling accessory 200 includes an attachment-surface exterior member (exterior surface) 204 that is attached to the camera body 100. The attachment-surface exterior member 204 has an accessory intake and exhaust port (first intake and exhaust port) 204a capable of intake and exhaust of a fluid inside the camera body 100. The accessory intake and exhaust port 204a has a shape that is longer in a Y direction (second direction) than in a Z direction (first direction) in an in-plane direction (XZ plane) of the attachment-surface exterior member 204. The accessory intake and exhaust port 204a is connected so as to overlap the body intake and exhaust port 126a of the camera body 100. An accessory intake and exhaust port (second intake and exhaust port) 205a is provided in a top surface of the cooling accessory 200.

The attachment-surface exterior member 204 includes a connection terminal (accessory digital connection terminal, second connection terminal) 202. When the connection terminal 202 is connected to a connection terminal (body digital connection terminal, first connection terminal) 105a of the camera body 100, power supply from the camera body 100 to the cooling accessory 200 and transmission of a control signal are achieved. That is, when the connection terminal 202 is connected to the connection terminal 105a, the cooling accessory 200 can obtain driving power and control signals for fans 208 from the camera body 100 via the connection terminal 202.

The attachment-surface exterior member 204 further includes a heat dissipating member 203 extending from inside a cooling duct 207a to be described later. The heat dissipating member 203 is configured to contact the eyelets 127 of the camera body 100.

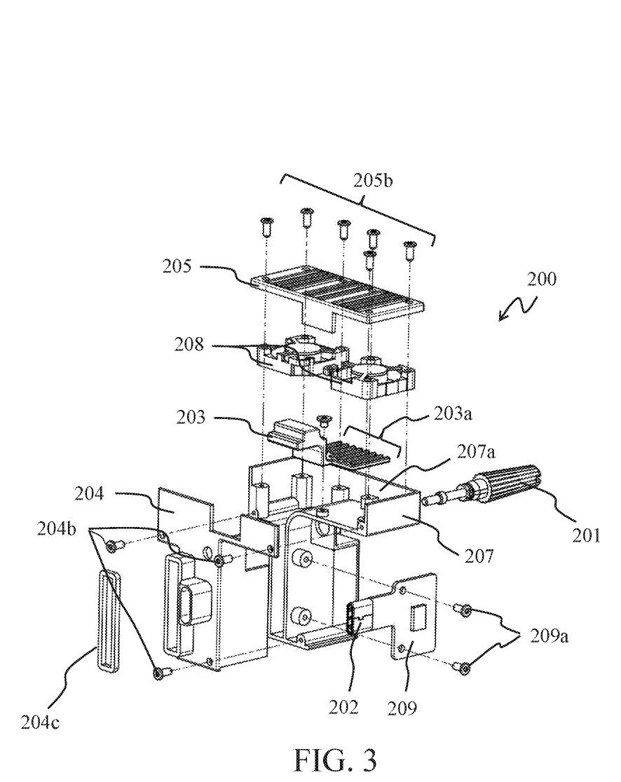

Next, with reference to FIG. 3, the internal structure of the cooling accessory 200 will be described. FIG. 3 is an exploded perspective view of the cooling accessory 200. A housing of the cooling accessory 200 includes the accessory body 207 made of a metal member or a resin member, the attachment-surface exterior member 204 having the accessory intake and exhaust port 204a, and a top exterior member 205 having the accessory intake and exhaust port 205a.

An elastic member 204c is provided around an entire perimeter of the accessory intake and exhaust port 204a, and is configured to closely contact an entire perimeter of the body intake and exhaust port 126a of the camera body 100. The accessory body 207 forms a cooling duct 207a that constitutes a flow path through which a fluid such as air passes between the accessory intake and exhaust port 204a and the accessory intake and exhaust port 205a.

The attachment-surface exterior member 204 is fixed to the accessory body 207 by screws 204b, and the top exterior member 205 is fixed to the accessory body 207 by screws 205b. In the flow path of the accessory body 207, each fan 208 is fixed to the accessory body 207 by the screws 205b. Thereby, a fluid such as air can be delivered from the accessory intake and exhaust port 204a to the accessory intake and exhaust port 205a, or from the accessory intake and exhaust port 205a to the accessory intake and exhaust port 204a. Thus, each fan 208 is a cooling unit provided inside the cooling duct 207a, and moves a fluid between an interior of the camera body 100 and an interior of the cooling duct 207a via the accessory intake and exhaust port 204a. Each fan 208 may form a flow path for a fluid flowing in the Y direction inside the cooling duct 207a.

The accessory intake and exhaust port 205a, whose normal direction is the Y direction, may be disposed with the Y direction as a normal direction. Each fan 208 intakes and exhausts a fluid inside the cooling duct 207a between the accessory intake and exhaust port 204a, which is provided with the X direction as a normal direction, and the accessory intake and exhaust port 205a.

The heat dissipating member 203 is provided below the fans 208, and fin portions 203a of the heat dissipating member 203 are arranged inside the cooling duct 207a of the accessory body 207. An accessory control substrate (accessory control board) 209 including the connection terminal 202 is fixed to the accessory body 207 by screws 209a inside the accessory body 207. Power is supplied to the accessory control substrate 209 from the connection terminal 105a of the camera body 100. Thereby, the accessory control substrate 209 can control the rotation of the fans 208. The present embodiment is not limited to this example, and the cooling accessory 200 may include a battery therein or supply power to the accessory control substrate 209 by connecting an external power cable.

### ATTACHMENT STRUCTURE OF COOLING ACCESSORY 200

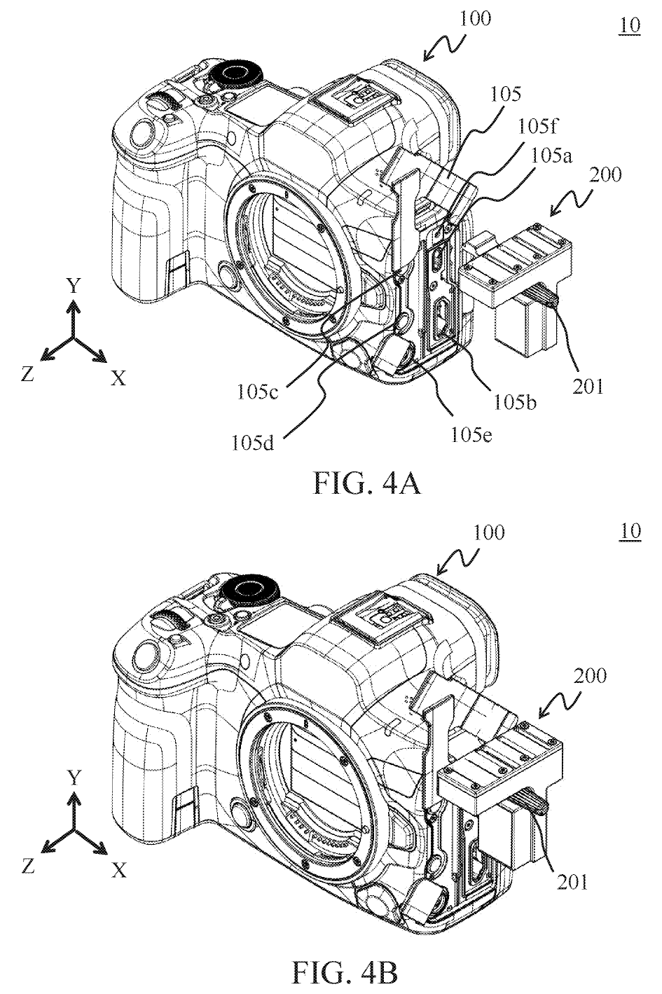

Next, with reference to FIGS. 4A and 4B, an attachment structure of the cooling accessory 200 to the camera body 100 will be described. FIGS. 4A and 4B are external views of an imaging system 10 that includes the camera body 100 and the cooling accessory 200. FIGS. 4A and 4B illustrate an example structure in which the cooling accessory 200 is directly attached to the camera body 100. FIG. 4A illustrates a state before the cooling accessory 200 is attached, and FIG. 4B illustrates a state after the cooling accessory 200 is attached.

FIG. 4A illustrates a state in which a terminal cover 105 of the camera body 100 is opened. Inside the terminal cover 105, there are provided the connection terminal 105a, a video output terminal 105b, an external microphone terminal 105c, a headphone terminal 105d, a remote-control terminal 105e, and a screw hole (first hole portion) 105f for attaching the cooling accessory 200. The connection terminal 105a, the video output terminal 105b, the external microphone terminal 105c, the headphone terminal 105d, and the remote-control terminal 105e are arranged in a terminal region of the camera body 100.

The connection terminal 105a of the camera body 100 and the connection terminal 202 of the cooling accessory 200 are connected, and the screw hole 105f in the camera body 100 and the attachment screw 201 of the cooling accessory 200 are connected. That is, when the cooling accessory 200 is attached to the camera body 100, the attachment screw 201 is fixed to the screw hole 105f in the camera body 100. Thereby, as illustrated in FIG. 4B, the cooling accessory 200 can be attached to the camera body 100. At this time, the accessory intake and exhaust port 204a and the body intake and exhaust port 126a of the camera body 100 overlap each other and are sealed by the elastic member 204c of the accessory intake and exhaust port 204a.

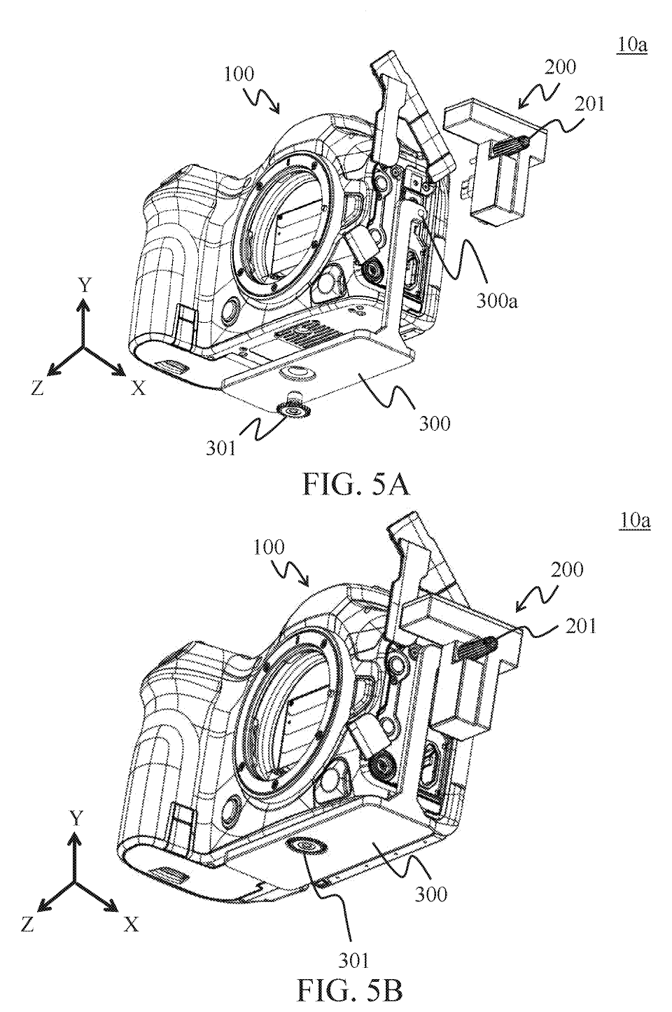

Next, with reference to FIGS. 5A and 5B, a description will be given of a structure example for attaching the cooling accessory 200 to the camera body 100 via a rig accessory 300 for attaching the camera body 100 to a tripod. FIGS. 5A and 5B are external views of an imaging system 10a including the camera body 100, the cooling accessory 200, and the rig accessory 300. FIG. 5A illustrates a state before the cooling accessory 200 is attached, and FIG. 5B illustrates a state after the cooling accessory 200 is attached.

The rig accessory 300 is made of a metal member and is fixed to the tripod seat 123 of the camera body 100 by a tripod screw 301. The rig accessory 300 has an accessory attachment screw hole (second hole portion) 300a, which can be connected to the attachment screw 201 of the cooling accessory 200. That is, the attachment screw 201 is fixed to the screw hole 300a in the rig accessory 300. As described above, even in a case where the camera body 100 is not provided with the screw hole 105f for attaching the cooling accessory 200, the cooling accessory 200 can be attached to the camera body 100 using the rig accessory 300.

### Circuit Configuration of Camera Body 100 and Cooling Accessory 200

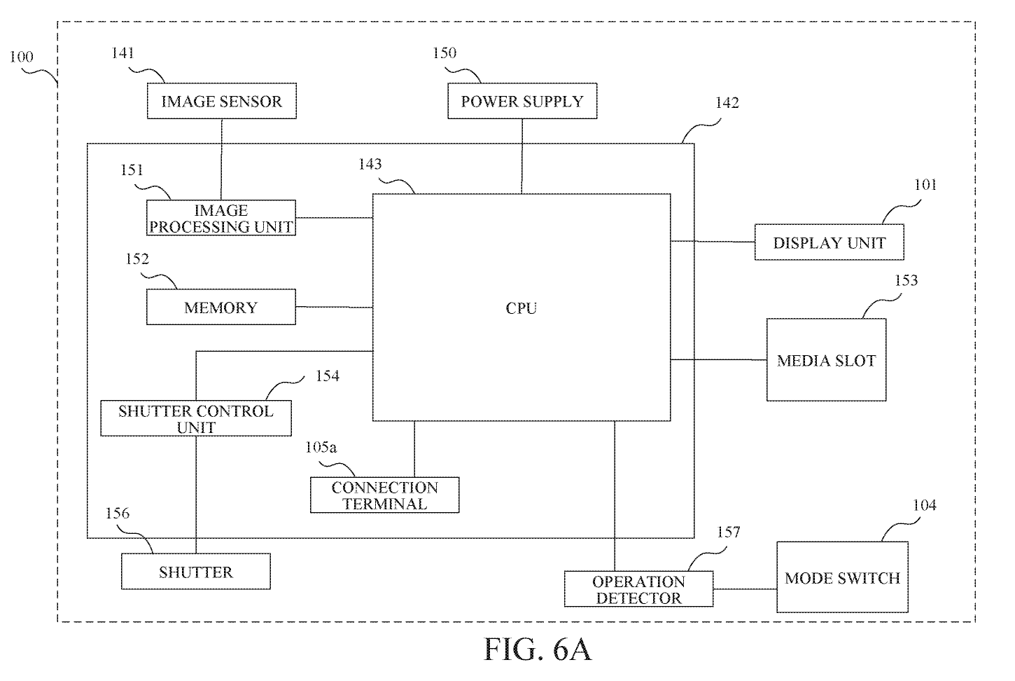

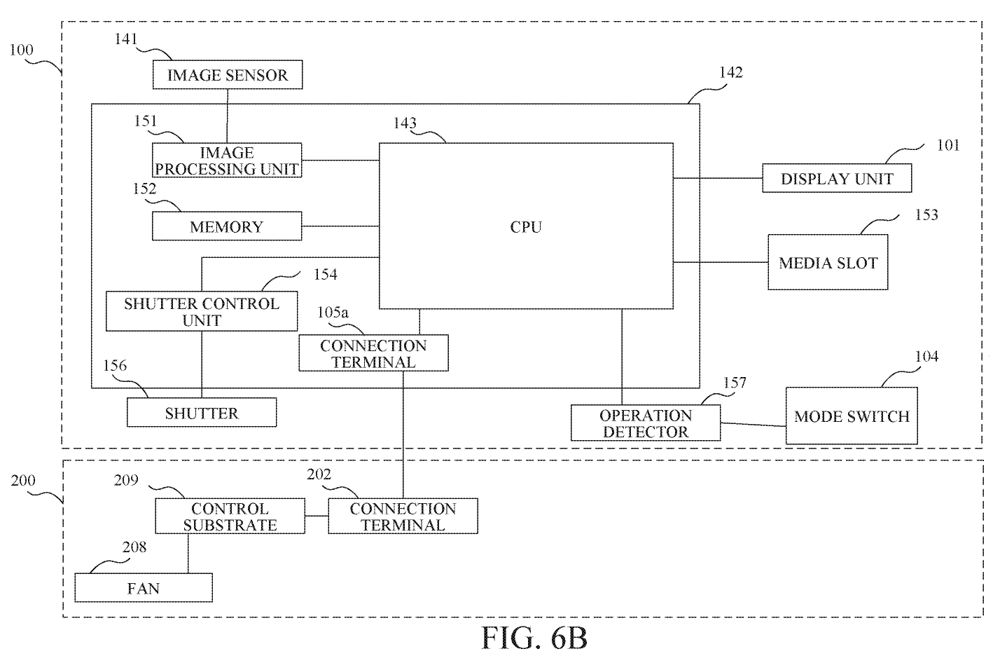

Next, with reference to FIGS. 6A and 6B, the circuit configurations of the camera body 100 and the cooling accessory 200 will be described. FIG. 6A is a block diagram of the camera body 100 in a state before the cooling accessory 200 is attached (the state of FIG. 4A). FIG. 6B is a block diagram of the camera body 100 and the cooling accessory 200 (imaging system 10) in a state where the cooling accessory 200 is attached (the state of FIG. 4B).

First, with reference to FIG. 6A, an operation of the camera body 100 in the state of FIG. 4A will be described. A central processing unit (CPU) 143 is a control unit that performs overall operation control of the camera body 100, and executes various processing and instructions for each circuit unit. A main circuit board 142 is mounted with a variety of components such as the CPU 143, which is one of heat generating components. The main circuit board 142 is a printed wired board (PWB). A camera microcomputer and various electrical circuits (detection circuits, control circuits, and processing circuits) are mounted on the main circuit board 142.

The CPU 143 controls each functional block of the camera body 100 and performs calculations for the control in accordance with a computer program read from a memory 152. A power supply 150 supplies electric power to each circuit unit in the camera body 100. An image sensor 141 includes a photoelectric conversion element such as a CCD sensor or a CMOS sensor, and converts an optical image of an object formed by an interchangeable lens (imaging optical system) into an image signal. An image signal obtained by the image sensor 141 is converted into image data by an image processing unit 151 and output to the CPU 143.

A shutter 156 is disposed in front of the image sensor 141 and adjusts an exposure time of the image sensor 141. A shutter control unit 154 drives the shutter 156 based on a signal input from the CPU 143. When a mode switch 104 is operated by the user, an operation detector 157 outputs a signal to the CPU 143 to change an imaging condition such as exposure and shutter speed. The camera body 100 can select a desired moving image capturing mode from among a plurality of moving image capturing modes by operating the mode switch 104. The moving image capturing modes include, for example, a high image quality mode and a low image quality mode. During moving image capturing in the high image quality mode, processing loads on the image sensor 141 and the CPU 143 increase, and thus the amounts of heat generated by these electronic components and a medium (not illustrated) increase. When the heat generation amount increases and exceeds an allowable temperature, thermal runaway and reduction in product lifetime may occur, and therefore a moving image capturing time may be reduced.

In order to solve this problem, in the present embodiment, as described with reference to FIG. 3, the cooling accessory 200 can be attached to the camera body 100, as necessary. On the other hand, in the low image quality mode, since the amounts of heat generated by these components are smaller than those in the high image quality mode, the moving image capturing time increases.

Next, with reference to FIG. 6B, a circuit configuration of the camera body 100 and the cooling accessory 200 in the state of FIG. 4B will be described. Here, only differences from FIG. 6A will be described. In the cooling accessory 200, as described above, electric power is supplied to the accessory control substrate 209 from the connection terminal 105a of the camera body 100 via the connection terminal 202. When power is supplied to the accessory control substrate 209 in the cooling accessory 200, the accessory control substrate 209 automatically controls driving of the fans 208. Alternatively, the accessory control substrate 209 can control driving of the fans 208 based on a signal input from the CPU 143 via the connection terminal 105a and the connection terminal 202.

### Flow Path Shape of Cooling Accessory 200

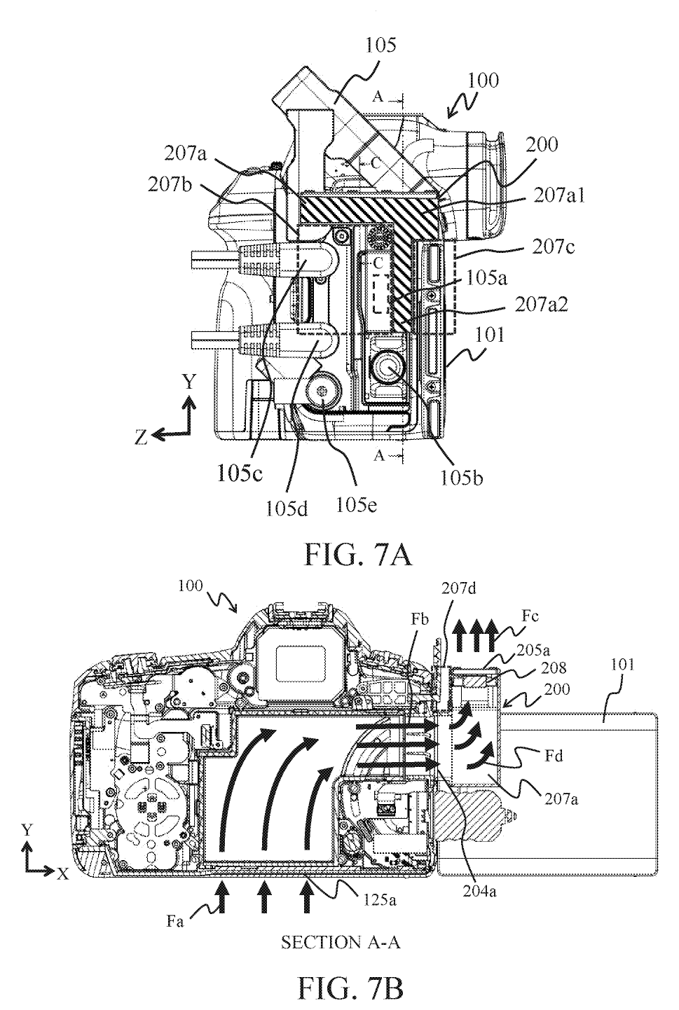

Next, with reference to FIGS. 7A, 7B, 8A, 8B, 9, and 10, a flow path shape of the accessory body 207 of the cooling accessory 200 will be described.

FIG. 7A is a side view of a state in which the cooling accessory 200 is attached to the camera body 100. FIG. 7A illustrates a state in which terminal cables are connected to the video output terminal 105b, the external microphone terminal 105c, the headphone terminal 105d, and the remote-control terminal 105e of the camera body 100, and the rear display unit 101 is opened relative to the camera body 100.

In FIG. 7A, a cooling duct 207a of the accessory body 207 is indicated by a hatched portion. The cooling duct 207ahas a shape in which a terminal-portion avoidance region 207b is cut away so as not to interfere with the terminal cables, and an accommodation region 207c of the rear display unit 101 is cut away so as not to interfere with the rear display unit 101. In other words, the cooling duct 207aincludes a first region 207a1 and a second region 207a2 closer to the fans 208 than the first region 207a1, and (a width of) the first region 207a1 in the Z direction is narrower than (a width of) the second region 207a2. Each of the first region 207a1 and the second region 207a2 indicates an region when viewed from an attachment surface side to the camera body 100 (when viewed along the X direction).

The terminal-portion avoidance region 207b includes a connection region between the connection terminal 105a of the camera body 100 and the connection terminal 202 of the cooling accessory 200. Thereby, the cooling accessory 200 can be attached to the camera body 100 even in a state where each terminal cable is connected to the camera body 100 and the rear display unit 101 is opened.

FIG. 7B is a sectional view taken along a line A-A in FIG. 7A. FIG. 7B illustrates a body duct from the body intake and exhaust port 125a to the body intake and exhaust port 126a in the camera body 100, and the cooling duct 207a extending to the accessory intake and exhaust port 205a through the connected accessory intake and exhaust port 204a. The cooling duct 207ais configured to avoid a terminal-cover avoidance region (interference region) 207d so as not to interfere when the terminal cover 105 is opened.

In FIG. 7B, flow directions of a fluid such as air flowing through each intake and exhaust port are indicated by arrows F. For example, when the fans 208 disposed in front of the accessory intake and exhaust port 205a rotates so as to exhaust air from the accessory intake and exhaust port 205a, flow paths Fa, Fb, Fc, and Fd are formed. The flow path Fa is a flow path of air taken in from the body intake and exhaust port 125a. The flow path Fb is a flow path passing through the accessory intake and exhaust port 204a. The flow path Fc is a flow path for exhausting air from the accessory intake and exhaust port 205a. The flow path Fd is a flow path formed by the flow path Fb passing through the accessory intake and exhaust port 204a.

At this time, the fans 208 are disposed such that a direction of the flow path Fc for exhausting air from the accessory intake and exhaust port 205a is perpendicular to a direction of the flow path Fb passing through the accessory intake and exhaust port 204a. By placing the fans 208 in this manner, even when the cooling accessory 200 is attached to the camera body 100, an increase in size of the imaging system 10 in the X direction (horizontal direction) can be suppressed. The flow path Fc in which air is taken in and exhausted from the accessory intake and exhaust port 205a by the fans 208 is formed toward a top surface direction (Y direction) of the camera body 100. Thereby, when a user looks into the finder 119 of the camera body 100 and grips a bottom surface portion thereof, the intake or exhaust air can be prevented from being directed toward the user.

Thus, the cooling accessory 200 may be attached to a side surface (YZ plane) of the camera body 100. The cooling accessory 200 may be attached to the side surface of the camera body 100 so as to avoid a terminal region of the camera body 100 (a region in which terminal portions 105a to 105e are arranged). The cooling accessory 200 may be attached to the side surface of the camera body 100 so as to avoid a movable region of the rear display unit 101 of the camera body 100 (accommodation region 207c). The cooling accessory 200 may be attached so as to avoid an interference region (terminal-cover avoidance region 207d) with the terminal cover 128 in a state where the terminal cover 128 for protecting the terminal region of the camera body 100 is opened. The side surface of the camera body 100 may be a surface opposite to the grip portion 121 among two side surfaces of the camera body 100 that face each other in a horizontal direction (X direction). The fans 208 may be configured to take into the cooling duct 207aa fluid that is taken in from a bottom surface of the camera body 100 and exhausted from the side surface of the camera body 100, and to exhaust the intake fluid from a top surface of the cooling accessory 200.

In the present embodiment, the flow direction described above may be reversed by controlling the fans 208. That is, a flow path may be formed in which air is taken in from the accessory intake and exhaust port 205a and exhausted from the body intake and exhaust port 125a.

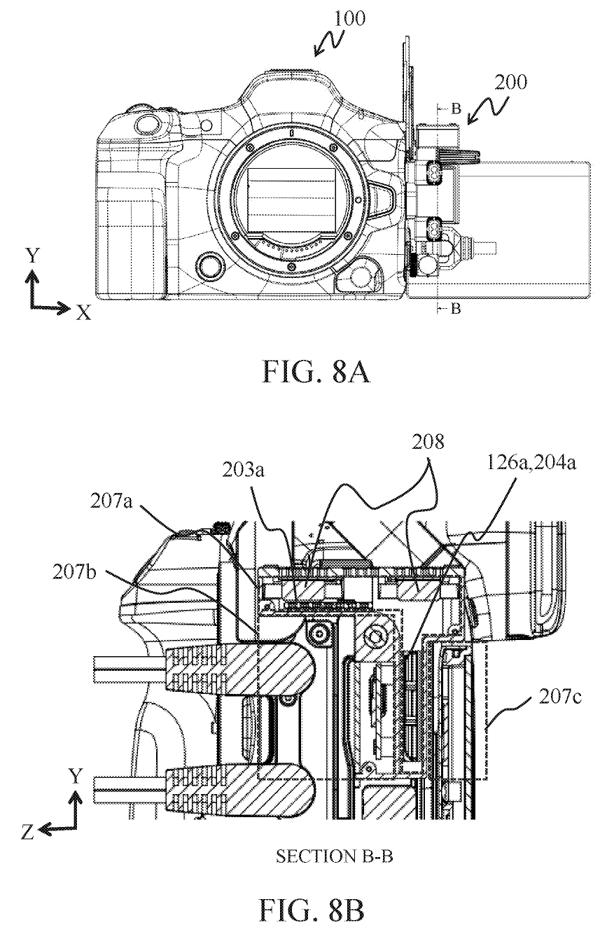

FIG. 8A is a front view of the imaging system 10 in a state where the cooling accessory 200 is attached to the camera body 100. FIG. 8B is a sectional view taken along a line B-B in FIG. 8A. FIG. 8B illustrates the interior of the cooling duct 207a of the accessory body 207.

As described above, the cooling duct 207ahas a cutout shape including the terminal-portion avoidance region 207b and the accommodation region 207c for the rear display unit 101. The body intake and exhaust port 126a and the accessory intake and exhaust port 204a are disposed in a region between the terminal-portion avoidance region 207b and the accommodation region 207c for the rear display unit 101. The body intake and exhaust port 126a and the accessory intake and exhaust port 204a are openings having a longitudinal shape extending in a height direction (Y direction) of the camera body 100 (a substantially rectangular shape in which a length in the Y direction is longer than a length in the Z direction). At least one of the fans 208 is disposed so as to overlap the openings of the body intake and exhaust port 126a and the accessory intake and exhaust port 204a in a longitudinal direction (Y direction). That is, when viewed from the X direction, at least a part of the fans 208 is disposed at a position on a line extending along the Y direction through the opening of the accessory intake and exhaust port 204a. Thereby, ventilation resistance of the flow path Fd formed at the body intake and exhaust port 126a and the accessory intake and exhaust port 204a by the fans 208 may be reduced, and a loss in flow rate may be suppressed.

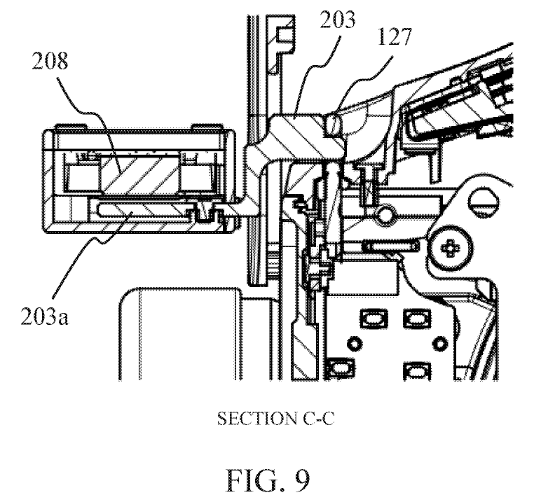

FIG. 9 is a sectional view taken along a line C-C in FIG. 7A and illustrates a cross section of a heat dissipating member 203 of the cooling accessory 200. In a case where the cooling accessory 200 is attached to the camera body 100, the heat dissipating member 203 contacts the eyelets 127 of the camera body 100. As described above, the eyelets 127 are connected to a metal housing or an exterior member of the camera body 100, and when the camera body 100 generates heat during moving image capturing or the like, heat is transferred via the eyelets 127 to the heat dissipating member 203 of the cooling accessory 200. The fin portions 203a of the heat dissipating member 203 are arranged below the fans 208 and may be air-cooled by a flow path formed by the fans 208.

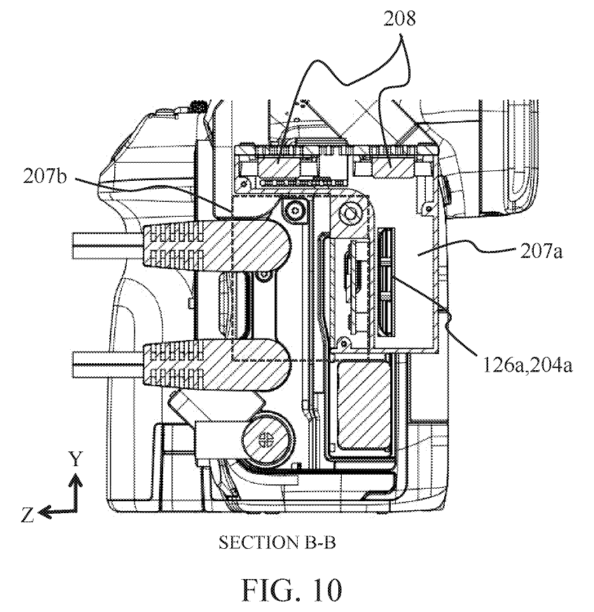

FIG. 10 is a sectional view taken along a line B-B in FIG. 8A illustrating another structure example different from that of FIG. 8B. For example, in a case where the rear display unit 101 provided on the camera body 100 is not of an openable/closable type (in a case where the rear display unit 101 is fixed to the camera body 100), the accommodation region 207c for the rear display unit 101 is unnecessary in the cooling duct 207a of the accessory body 207. This structure example illustrates a case in which the accessory body 207 does not include the accommodation region 207c.

The cooling duct 207ahas a cutout shape including only the terminal-portion avoidance region 207b, and compared with the structure including the accommodation region 207c described above, the space inside the cooling duct 207a may be increased. Thereby, ventilation resistance of the flow path Fb formed at the body intake and exhaust port 126a and the accessory intake and exhaust port 204a by the fans 208 may be reduced, and a loss in flow rate may be suppressed.

With the cooling accessory of the present embodiment, even in a state where the cooling accessory is attached to an electronic apparatus such as an image pickup apparatus, portability can be maintained, influences such as vibration can be suppressed without increasing the height of the imaging optical axis position, and a flow path for an air-blowing unit can be secured to enhance cooling performance. Thus, the present embodiment can provide a cooling accessory with improved user convenience.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-037102, filed on March 10, 2025, and which is hereby incorporated by reference herein in its entirety.

What is claimed is:

1. A cooling accessory attachable to an electronic apparatus, the cooling accessory comprising:
an exterior surface having a first intake and exhaust port configured to intake and exhaust a fluid inside the electronic apparatus;
a cooling duct through which the fluid flows; and
a cooling unit provided inside the cooling duct,
wherein the cooling unit is configured to move the fluid between an inside of the electronic apparatus and an inside of the cooling duct through the first intake and exhaust port,
wherein the first intake and exhaust port has a shape that is longer in a second direction than in a first direction in an in-plane direction of the exterior surface,
wherein the cooling duct includes a first region and a second region disposed closer to the cooling unit than the first region, and
wherein the first region in the first direction is narrower than the second region in the first direction.

2. The cooling accessory according to claim 1, wherein, when viewed from a third direction perpendicular to both the first direction and the second direction, at least a part of the cooling unit is disposed at a position from the first intake and exhaust port along the second direction.

3. The cooling accessory according to claim 1, wherein the cooling unit is a fan configured to form a flow path for the fluid that flows through the cooling duct in the second direction.

4. The cooling accessory according to claim 1, wherein the cooling duct has a second intake and exhaust port having a normal direction that is the second direction, and
wherein the cooling unit is configured to intake and exhaust the fluid inside the cooling duct between the first intake and exhaust port, which has a normal direction that is a third direction perpendicular to the first direction and the second direction, and the second intake and exhaust port.

5. The cooling accessory according to claim 1, further comprising:
a heat dissipating member disposed inside the cooling duct,
wherein the heat dissipating member dissipates heat of the electronic apparatus to the heat dissipating member by contacting a metal member of the electronic apparatus to which the cooling accessory is attached.

6. The cooling accessory according to claim 5, wherein the metal member is an eyelet.

7. The cooling accessory according to claim 1, further comprising:
a second connection terminal connectable to a first connection terminal of the electronic apparatus,
wherein, in a case where the second connection terminal is connected to the first connection terminal, the cooling accessory acquires driving power and a control signal for the cooling unit from the electronic apparatus via the second connection terminal.

8. The cooling accessory according to claim 7, wherein the second connection terminal is provided on the exterior surface.

9. The cooling accessory according to claim 1, further comprising:
a fixing member fixed to a first hole portion in the electronic apparatus when the cooling accessory is attached to the electronic apparatus.

10. The cooling accessory according to claim 1, further comprising:
a fixing member fixed to a second hole portion in a rig accessory attachable to a tripod seat of the electronic apparatus.

11. The cooling accessory according to claim 1, wherein the cooling accessory is attachable to a side surface of the electronic apparatus.

12. The cooling accessory according to claim 11, wherein the cooling accessory is attachable to the side surface of the electronic apparatus so as to avoid a terminal region of the electronic apparatus to which a cable is to be connected.

13. The cooling accessory according to claim 11, wherein the cooling accessory is attachable to the side surface of the electronic apparatus so as to avoid a movable region of a movable display unit of the electronic apparatus.

14. The cooling accessory according to claim 11, wherein the cooling accessory is attachable to the side surface of the electronic apparatus so as to avoid an interference region with a terminal cover for protecting a terminal region of the electronic apparatus while the terminal cover opens.

15. The cooling accessory according to claim 11, wherein the side surface of the electronic apparatus is a surface opposite a grip portion of the electronic apparatus among two side surfaces facing each other in a horizontal direction of the electronic apparatus.

16. The cooling accessory according to claim 1, wherein the cooling unit is configured to take into the cooling duct air that has been taken in from a bottom surface of the electronic apparatus and exhausted from a side surface of the electronic apparatus, and to exhaust the air from a top surface of the cooling accessory.
